(19) United States
(12) Patent Application Publication
(10) Pub. No.: US 2024/0284722 A1
(43) Pub. Date: Aug. 22, 2024

(54) DISPLAY PANEL

(71) Applicant: Wuhan China Star Optoelectronics Semiconductor Display Technology Co., Ltd., Wuhan (CN)

(72) Inventor: Hang YAN, Wuhan (CN)

(21) Appl. No.: 18/473,249

(22) Filed: Sep. 24, 2023

(30) Foreign Application Priority Data
Feb. 16, 2023 (CN) 202310137279.7

(51) Int. Cl. H10K 59/124; H10K 59/131

(52) U.S. Cl. CPC H10K 59/124; H10K 59/131; H10K 59/80515

(57) ABSTRACT

The present application discloses a display panel. The display panel includes a substrate, an inorganic insulating layer disposed on a side of the substrate, a first metal layer disposed on a side of the inorganic insulating layer away from the substrate, a first organic insulating layer disposed on a side of the first metal layer away from the substrate, and a second metal layer disposed on the side of the first organic insulating layer away from the substrate. The first metal layer includes a first metal trace having a first trace portion. A first groove is provided on a side of the first organic insulating layer away from the substrate. The second metal layer includes a first electrode. The first electrode covers the first groove, and a minimum distance between the first electrode and the first trace portion is greater than or equal to 1.2 μm.

### CROSS-REFERENCE TO RELATED APPLICATION

This application claims priority to Chinese Patent Application No. 202310137279.7, filed on Feb. 16, 2023, which is hereby incorporated by reference in its entirety.

### TECHNICAL FIELD

The present application relates to a field of display technologies, and more particularly, to a display panel.

### BACKGROUND

Organic light-emitting diode (OLED) display panels have been widely used in people's lives, such as display screens of mobile phones, computers, vehicles, and the like. The organic light-emitting diode display panel includes a plurality of light-emitting devices, and the light-emitting devices emit display lights to display images.

However, the current light-emitting devices have a low light-emitting efficiency, and a large amount of display lights cannot be emitted and is confined in the light-emitting devices.

### SUMMARY

An embodiment of the present application provides a display panel, which can solve the problem that the current light-emitting devices have low light-emitting efficiency, and a large amount of display lights cannot be emitted and is confined in the light-emitting devices.

An embodiment of the present application provides a display panel including a plurality of pixel display areas, and a non-display area between the pixel display areas; wherein the display panel further includes: a substrate; an inorganic insulating layer disposed on a side of the substrate; a first metal layer disposed on a side of the inorganic insulating layer away from the substrate, wherein the first metal layer includes a plurality of first metal traces, each of the first metal traces includes a first trace portion overlapped with a corresponding one of the pixel display areas; a first organic insulating layer disposed on a side of the first metal layer away from the substrate, wherein a first groove is provided on a side of the first organic insulating layer away from the substrate, and the first groove is disposed corresponding to the first trace portion; and a second metal layer disposed on the side of the first organic insulating layer away from the substrate, wherein the second metal layer includes a plurality of first electrodes disposed corresponding to the pixel display area; and wherein each of the first electrodes covers the first groove, and a minimum distance between the first electrode and the first trace portion of the first metal trace corresponding to the first electrode is greater than or equal to 1.2 μm.

In some embodiments, the minimum distance between the first electrode and the first trace portion of the first metal trace corresponding to the first electrode is less than or equal to 4 μm.

In some embodiments, the first organic insulating layer has a thickness less than or equal to 4 μm.

In some embodiments, the first organic insulating layer includes: a first organic sub-insulating layer disposed on the side of the first metal layer away from the substrate; wherein a minimum distance between an area of the first organic sub-insulating layer corresponding to the first trace portion and the substrate is greater than a minimum distance between the first metal trace and the substrate; and a second organic sub-insulating layer disposed on a side of the first organic sub-insulating layer away from the substrate, wherein the first groove is disposed on a side of the second organic sub-insulating layer away from the substrate

In some embodiments, a thickness of the first organic sub-insulating layer on the inorganic insulating layer is greater than a thickness of the first metal layer on the inorganic insulating layer.

In some embodiments, a thickness of the first organic sub-insulating layer in an area not corresponding to the first metal trace is less than or equal to 2 μm; and a thickness of the second organic sub-insulating layer in the area not corresponding to the first metal trace is less than or equal to 2 μm.

In some embodiments, the display panel further includes: a third metal layer disposed between the inorganic insulating layer and the first metal layer, wherein the third metal layer includes a plurality of second metal traces, each of the second metal traces includes a second trace portion overlapped with the pixel display area; and a second organic insulating layer disposed between the third metal layer and the first metal layer; wherein the second trace portion and the first trace portion are at least partially overlapped in the pixel display area; a minimum distance between the second trace portion and the first trace portion is greater than or equal to 1.2 μm.

In some embodiments, the first electrode includes a flat portion and a recessed portion, the recessed portion is attached with the first groove, and the flat portion is disposed around the first groove.

In some embodiments, the display panel includes a pixel definition layer and a second electrode, wherein the pixel definition layer is disposed on the second metal layer, and the second electrode is disposed on the pixel definition layer.

In some embodiments, the pixel definition layer has an opening, and the opening exposes the first electrode.

In some embodiments, a depth of the first groove is greater than 0 and less than or equal to 0.8 μm.

In some embodiments, an included angle between a side wall of the first groove and a bottom surface of the first groove ranges from 120° to 160°.

In some embodiments, the first organic insulating layer is provided with one first groove in the pixel display area, the first groove is located at a center of the pixel display area.

In some embodiments, a shape of the first groove matches a shape of the pixel display area.

In some embodiments, an outline of the first groove has a circular shape, a ring shape, an elliptical shape, a rectangular shape, and a square shape.

In some embodiments, an outline of the first groove has a first arc and a second arc, and the first arc is connected with the second arc. The first arc has a greater curvature radius than the second arc.

In some embodiments, the first organic insulating layer is provided with a plurality of first grooves in the pixel display area, the first grooves are uniformly arranged in the pixel display area.

In some embodiments, a first through-hole is provided on the first electrode, to connect the first electrode to a thin film transistor.

According to the present application, a first groove is provided on the side of the first organic insulating layer away from the substrate, and the first groove is disposed corresponding to the first trace portion; and the second metal layer includes a plurality of first electrodes provided corresponding to pixel display areas, the first electrode is an anode of the light-emitting device of the display panel. As such, the first groove can fail a condition for total reflection of the display lights in the light-emitting device. Thus, the display lights trapped in the light-emitting device due to the total reflection can be reflected out, thereby increasing the light-emitting efficiency of the light-emitting device. At the same time, the planarization effect of the first organic insulating layer is ensured, and the adverse effect of the protrusions of the first metal trace on the first electrode is avoided.

### BRIEF DESCRIPTION OF THE DRAWINGS

In order to explain the technical solution in the embodiments of the present application more clearly, reference is made briefly to the drawings required for the description of the embodiments. It should be understood that the drawings in the following description are for merely some of the embodiments of the present application, and other drawings may be made to those skilled in the art without involving any inventive effort.

FIG. 1 is a cross-sectional view of a partial film layer of a display panel according to Embodiment 1 of the present application.

FIG. 2 is a cross-sectional view of a partial film layer of a display panel according to Embodiment 2 of the present application.

FIG. 3 is a cross-sectional view of a partial film layer of a display panel according to Embodiment 3 of the present application.

FIG. 4 is a top view of a first partial area of a display panel according to Embodiment 4 of the present application.

FIG. 5 is a top view of a second partial area of a display panel according to Embodiment 4 of the present application.

FIG. 6 is a top view of a third partial area of a display panel according to Embodiment 4 of the present application.

FIG. 7 illustrates the parasitic capacitance between the first electrode and the first trace portion changing with the distance between the first electrode and the first trace portion.

### DETAILED DESCRIPTION OF THE EMBODIMENTS

The technical solutions in the embodiments of the present application is clearly and completely described in connection with the drawings in the embodiments of the present application. It should be understood that the described embodiments are merely a part of the embodiments of the present application, rather than all the embodiments. Based on the embodiments in the present application, all other embodiments obtained by a person skilled in the art without involving any inventive effort are in the protection scope of the present application. Furthermore, it should be understood that the described embodiments herein are for purposes of illustration and explanation only, and are not intended to limit the application. In the present application, if not stated to the contrary, the use of positional terms such as “on” and “under” refer to the position on and under the device in actual use or operation, specifically as shown in the drawings. Moreover, the terms “in” and “out” refer to the outline of the device.

An embodiment of the present application provides a display panel. The display panel includes a plurality of pixel display areas, and a non-display area between the pixel display areas. The display panel further includes: a substrate; an inorganic insulating layer disposed on a side of the substrate; a first metal layer disposed on a side of the inorganic insulating layer away from the substrate, a first organic insulating layer disposed on a side of the first metal layer away from the substrate; and a second metal layer disposed on a side of the first organic insulating layer away from the substrate. The first metal layer includes a plurality of first metal traces, and the first metal trace includes a first trace portion overlapped with the pixel display area. The side of the first organic insulating layer away from the substrate is provided with a first groove corresponding to the first trace portion. The second metal layer includes a plurality of first electrodes disposed corresponding to the pixel display areas, wherein the first electrode covers the first groove, and the minimum distance between the first electrode and the first trace portion of the corresponding first metal trace is greater than or equal to 1.2 μm. Detailed descriptions are given below. It should be noted that the order in which the following embodiments are described is not intended to limit the preferred order of the embodiments.

### Embodiment 1

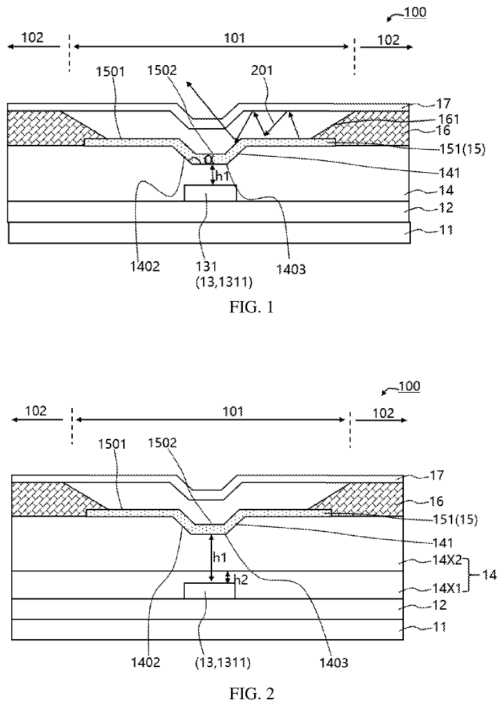

Referring to FIG. 1, FIG. 1 is a cross-sectional view of a first partial film layer of a display panel according to Embodiment 1 of the present application.

This embodiment provides a display panel 100 including a plurality of pixel display areas 101, and a non-display area 102 between the pixel display areas 101. The display panel 100 further includes a substrate 11, an inorganic insulating layer 12, a first metal layer 13, a first organic insulating layer 14, and a second metal layer 15. The inorganic insulating layer 12 is provided on a side of the substrate. The first metal layer 13 is provided on a side of the inorganic insulating layer 12 away from the substrate 11, and includes a plurality of first metal traces 131. Each of the first metal traces 131 includes a first trace portion 1311 overlapped with the pixel display area 101. The first organic insulating layer 14 is disposed on a side of the first metal layer 13 away from the substrate 11. A first groove 141 is provided on a side of the first organic insulating layer 14 away from the substrate 11, and the first groove 141 is disposed corresponding to the first trace portion 1311. The second metal layer 15 is disposed on a side of the first organic insulating layer 14 away from the substrate 11, and includes a plurality of first electrodes 151 disposed corresponding to the pixel display areas 101. Each of the plurality of first electrodes 151 covers the first groove 141, and the minimum distance between the first electrode 151 and the first trace portion 1311 of the first metal trace 131 corresponding to the first electrode 151 is greater than or equal to 1.2 μm.

In an embodiment, the substrate 11 may be a flexible substrate or a glass substrate, which is not limited herein.

In an embodiment, the display panel 100 includes a plurality of pixel display areas 101, and a non-display area 102 between any two pixel display areas 101. That is, the pixel display areas 101 and the non-display areas 102 are alternately provided.

The layer structure of the display panel 100 shown in FIG. 1 includes: a substrate 11, an inorganic insulating layer 12, a first metal layer 13, a first organic insulating layer 14, a second metal layer 15, a pixel definition layer 16, a light-emitting material layer (disposed between the first electrode 151 and the second electrode 17), and a second electrode 17. However, the display panel 100 may include other layer structures, which are not limited herein.

In an embodiment, the pixel definition layer 16 may include a plurality of openings 161, and each of the plurality of openings 161 exposes the first electrode 151. It should be understood that the pixel display area 101 is an opening area of the pixel definition layer 16. The pixel display area 101 corresponds to an area where sub-pixels emit lights. The non-display area 102 corresponds to an area where sub-pixels do not emit lights, and is a non-opening area of the pixel definition layer 16.

In an embodiment, the first organic insulating layer 14 may be a flat layer, but is not limited thereto.

In an embodiment, the first electrode 151 may be an anode or a cathode, and the first electrode 151 is a reflective electrode. The first electrode 151 may reflect the display light 201. Preferably, the first electrode 151 is an anode of the light-emitting device, and the second electrode 17 is a cathode.

In an embodiment, a first groove 141 is disposed on a side of the first organic insulating layer 14 away from the substrate 11, and the first groove 141 corresponds to the first trace portion 1311. The first electrode 151 covers the first groove 141, and the first electrode 151 of the light-emitting device is attached to the first groove 141 to form the recessed portion 1502.

In an embodiment, the light-emitting device or the first electrode 151 includes a flat portion 1501 and a recessed portion 1502 located in the opening 161. Without the recessed portion 1502, the display lights 201 are repeatedly reflected in the flat portion 1501, as such the display lights 201 are trapped inside the light-emitting device and cannot be emitted from the light-emitting device. As a result, the light-emitting efficiency of the light-emitting device is reduced. As shown in FIG. 1, in a case that the recessed portion 1502 is provided, the display lights 201 reflected totally and repeatedly in the flat portion 1501 can enter the recessed portion 1502. As the first electrode 151 in the recessed portion 1502 is inclined to provide a slope (i.e., side wall 1402), the condition for total reflection of the display lights 201 is lost. Thus, the display lights 201 are emitted from the light-emitting device, thereby improving the light-emitting efficiency of the light-emitting device.

In the present embodiment, the first organic insulating layer 14 is provided with a first groove 141 corresponding to the first trace portion 1311 on a side away from the substrate 11, the second metal layer 15 includes a plurality of first electrodes 151 corresponding to pixel display area 101, and the first electrode 151 is the anode of the light-emitting device of the display panel 100. As such, the first groove 141 can fail the condition for total reflection of the display lights 201 in the light-emitting devices. Thus, the display lights 201 can be emitted out from the light-emitting device, thereby increasing the light-emitting efficiency of the light-emitting device. While the minimum distance between the first electrode 151 and the first trace portion 1311 of the first metal trace 131 corresponding to the first electrode 151 is greater than or equal to 1.2 μm, to avoid an excessive parasitic capacitance between the first electrode 151 and the first trace portion 1311, to prevent the parasitic capacitance from being too large to affect the driving performance of the thin film transistors and the potential stability of the first electrodes 151.

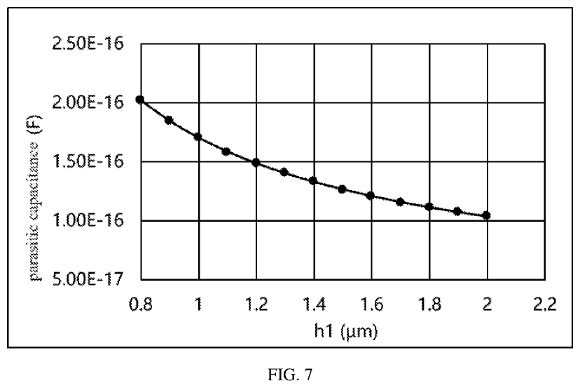

Referring to FIG. 7, a parasitic capacitance between the first electrode 151 and the first trace portion 1311 is shown to change the distance between the first electrode 151 and the first trace portion 1311.

In an embodiment, as shown in FIG. 7, it is shown that the parasitic capacitance between the first electrode 151 and the first trace portion 1311 varies with the distance between the first electrode 151 and the first trace portion 1311. The first distance h1 between the bottom surface 1403 and the first trace portion 1311 is defined, and the smaller the first distance h1, the greater the parasitic capacitance between the first electrode 151 and the first trace portion 1311. To meet the display requirement of the display panel 100 or the light-emitting device, the distance between the bottom surface 1403 and the first trace portion 1311 is greater than or equal to 1.2 μm, to reduce the influence of the electric field of the first trace portion 1311 on the first electrode 151, and to reduce the parasitic capacitance between the bottom surface 1403 and the first trace portion 1311.

In some embodiments, the minimum distance between the first electrode 151 and the first trace portion 1311 of the first metal trace 131 corresponding to the first electrode 151 is greater than or equal to 1.2 μm, and less than or equal to 4 μm.

Specifically, as shown in FIG. 1, the minimum distance between the first electrode 151 and the first trace portion 1311 of the first metal trace 131 corresponding to the first electrode 151 is greater than or equal to 1.2 μm, and less than or equal to 4 μm, that is, the first distance h1 is greater than or equal to 1.2 μm, and less than or equal to 4 μm.

Specifically, with the minimum distance between the first electrode 151 and the first trace portion 1311 of the first metal trace 131 corresponding to the first electrode 151 greater than or equal to 1.2 μm and less than or equal to 4 μm, an overthickness of the display panel 100 is avoided. At the same time, the planarization effect of the first organic insulating layer is ensured, and the adverse effect of the protrusions of the first metal trace on the first electrode is avoided.

In an embodiment, the minimum distance between the first electrode 151 and the first trace portion 1311 of the first metal trace 131 corresponding to the first electrode 151 is less than or equal to 4 μm, to avoid the thickness of the first organic insulating layer 14 from being too large. In a case that the thickness of the first organic insulating layer 14 is too large, the first organic insulating layer 14 may experience an incomplete curing and incomplete gas release, as such, the first organic insulating layer 14 may release gas subsequently to damage film subsequent layers, thereby reducing the production yield of the display panel. Therefore, the problem that the first organic insulating layer 14 may release gas subsequently due to the incomplete curing is eliminated with the minimum distance between the first electrode 151 and the first trace portion 1311 of the first metal trace 131 corresponding to the first electrode 151 less than or equal to 4 μm, or the thickness of the first organic insulating layer 14 is less than or equal to 4 μm.

In some embodiments, the depth of the first groove 141 is greater than 0, and less than or equal to 0.8 μm.

Specifically, the depth of the first groove 141 is less than or equal to 0.8 μm, and the depth of the first groove 141 should not be excessively large, to prevent the display lights 201 are from being trapped in the first groove 141 and cannot be emitted from the light-emitting device. As such, the light-emitting efficiency of the light-emitting device is improved.

In some embodiments, the included angle between the side wall 1402 of the first groove 141 and the bottom surface 1403 of the first groove 141 ranges from 120° to 160°.

Specifically, the surface of the first groove 141 close to the substrate 11 is the bottom surface 1403, and the side wall 1402 is connected the bottom surface 1403 to the flat portion 1501. The side wall 1402 surrounds the bottom surface 1403, and the side wall 1402 is obliquely disposed with respect to the flat portion 1501. The side wall 1402 fails the condition for the total reflection of the display lights 201 in the light-emitting device.

In an embodiment, the angle α between the side wall 1402 and the bottom surface 1403 is an obtuse angle, which can fail the condition for the total reflection of the display lights 201. Preferably, the angle α between the side wall 1402 and the bottom surface 1403 ranges from 120° to 160°. That is. the angle α between the side wall 1402 and the bottom surface 1403 is greater than or equal to 120° and less than or equal to 160°.

In an embodiment, in a case that the length or width of the bottom surface 1403 is 0 μm or close to 0 μm, the included angle α between the side wall 1402 and the bottom surface 1403 refers to the included angle between the side wall 1402 and the bottom surface in the first groove 141, or refers to the included angle between the side wall 1402 and the plane in which the bottom surface is located, wherein the plane in which the bottom surface 1403 is located is parallel to the substrate 11.

### Embodiment 2

The display panel of the present embodiment is the same as or similar to the display panel described in any one of the above-described embodiments, which is not described in detail. The differences between the Embodiment 1 and Embodiment 2 are described herein.

Referring to FIG. 2, FIG. 2 is a cross-sectional view of a partial film layer of a display panel according to Embodiment 2 of the present application.

In some embodiments, the first organic insulating layer 14 includes a first organic sub-insulating layer 14X1, and a second organic sub-insulating layer 14X2. The first organic sub-insulating layer 14X1 is disposed on a side of the first metal layer 13 away from the substrate 11. The minimum distance between the area of the first organic sub-insulating layer 14X1 corresponding to the first trace portion 1311 and the substrate 11 is greater than the minimum distance between the first metal trace 131 to the substrate 11. The second organic sub-insulating layer 14X2 is provided on a side of the first organic sub-insulating layer 14X1 away from the substrate 11, and the second organic sub-insulating layer 14X2 is provided with a first groove 141 corresponding to the first trace portion 1311 on the side of the second organic sub-insulating layer 14X2 away from the substrate 11.

Specifically, as shown in FIG. 2, the first organic insulating layer 14 includes the first organic sub-insulating layer 14X1 and the second organic sub-insulating layer 14X2 stacked, and the first groove 141 is disposed on a surface of the side of the second organic sub-insulating layer 14X2 away from the substrate 11.

Specifically, in the surface on the side of the first organic sub-insulating layer 14X1 away from the substrate 11, the minimum distance between the area of the first organic sub-insulating layer 14X1 corresponding to the first trace portion 1311 and the substrate 11 is greater than the minimum distance between the first metal trace 131 to the substrate 11, that is, the thickness of the first organic sub-insulating layer 14X1 on the inorganic insulating layer 12 is greater than the thickness of the first metal layer 13 on the inorganic insulating layer 12, as shown in FIG. 2. That is, the second distance h2 in FIG. 1 is greater than 0 μm.

Specifically, the first organic sub-insulating layer 14X1 is used for planarizing the first metal layer 13, and the second organic sub-insulating layer 14X2 is used for providing the first grooves 141.

In some embodiments, the first organic sub-insulating layer 14X1 has a thickness of less than or equal to 2 μm in the area not corresponding to the metal traces; and the second organic sub-insulating layer 14X2 has a thickness of less than or equal to 2 μm in the area not corresponding to the metal traces.

Specifically, as shown in FIG. 2, that is, the thickness of the first organic sub-insulating layer 14X1 on the inorganic insulating layer 12 is less than or equal to 2 μm, and the thickness of the second organic sub-insulating layer 14X2 on the first organic sub-insulating layer 14X1 is less than or equal to 2 μm.

Specifically, the thickness of the first organic sub-insulating layer 14X1 on the inorganic insulating layer 12 is less than or equal to 2 μm, and the thickness of the second organic sub-insulating layer 14X2 on the first organic sub-insulating layer 14X1 is less than or equal to 2 μm, as such, it is possible to avoid incomplete curing of the first organic sub-insulating layer 14X1 and the second organic sub-insulating layer 14X2, and incomplete gas release during manufacturing of the display panel, thereby preventing the first organic sub-insulating layer 14X1 and the second organic sub-insulating layer 14X2 from releasing gas release to damage the subsequent film layer, and improving the production yield of the display panel.

### Embodiment 3

The display panel of the present embodiment is the same as or similar to the display panel described in any one of the above-described embodiments, which is not described in detail. The differences between the Embodiment 3 and other Embodiments are described herein.

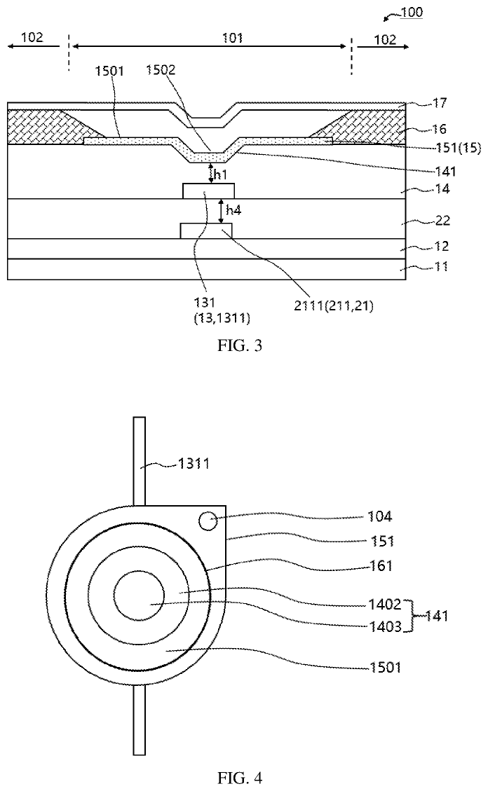

Referring to FIG. 3, FIG. 3 is a cross-sectional view of a partial film layer of a display panel according to Embodiment 3 of the present application.

In some embodiments, the display panel 100 further includes a third metal layer 21 disposed between the inorganic insulating layer 12 and the first metal layer 13, and a second organic insulating layer 22. The third metal layer 21 includes a plurality of second metal traces 211, and each of the second metal traces 211 includes a second trace portion 2111 overlapped with the pixel display area 101. The second organic insulating layer 22 is provided between the third metal layer 21 and the first metal layer 13. In the pixel display area 101, the second trace portion 2111 and the first trace portion 1311 are at least partially overlapped. At the area where the second trace portion 2111 and the first trace portion 1311 are overlapped, the minimum distance between the second trace portion 2111 and the first trace portion 1311 is greater than or equal to 1.2 μm. This is, the minimum distance h4 is greater than or equal to 1.2 μm.

Specifically, as shown in FIG. 3, the second trace portion 2111 and the first trace portion 1311 are at least partially overlapped, and the minimum distance between the second trace portion 2111 and the first trace portion 1311 is greater than or equal to 1.2 μm, to avoid excessive parasitic capacitance between the second trace portion 2111 and the first trace portion 1311 and to improve potential stability between the second trace portion 2111 and the first trace portion 1311.

### Embodiment 4

The display panel of the present embodiment is the same as or similar to the display panel described in any one of the above-described embodiments, which is not described in detail. The differences between the Embodiment 3 and other Embodiments are described herein.

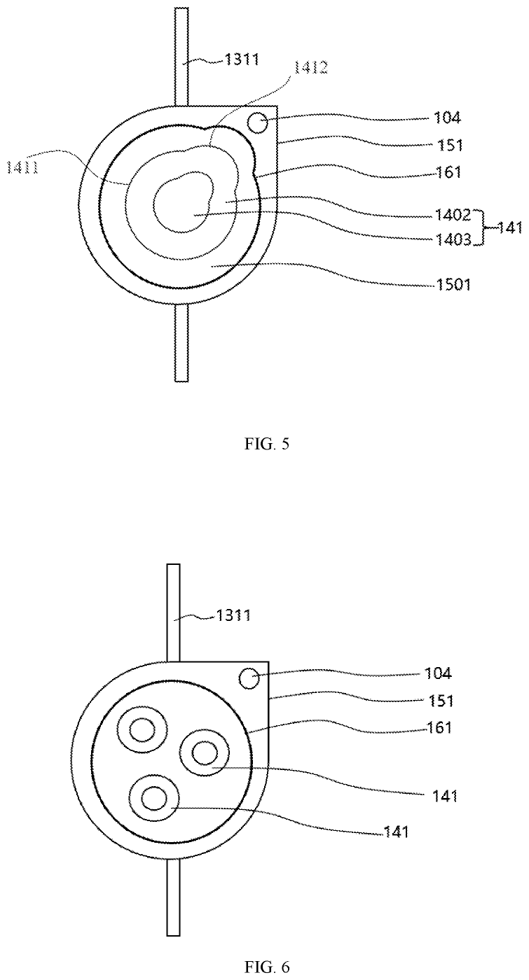

Referring to FIGS. 4-6, FIG. 4 is a top view of a first partial area of a display panel according to Embodiment 4 of the present application; FIG. 5 is a top view of a second partial area of a display panel according to Embodiment 4 of the present application; and FIG. 6 is a top view of a third partial area of a display panel according to Embodiment 4 of the present application.

In some embodiments, in the top view, the first organic insulating layer 14 is provided with one first groove 141 in a pixel display area 101, the first groove 141 is located in the center of the pixel display area 101.

Specifically, as shown in FIG. 4, the first organic insulating layer 14 is provided with one first groove 141 in a pixel display area 101, the first groove 141 is located at the center of the pixel display area 101, the flat portion 1501 is provided around the first groove 141, and the display lights 201 in the light-emitting device is converged at the first groove 141 for emitting, thereby improving the light output efficiency.

Specifically, the first organic insulating layer 14 is provided with one first groove 141 in a pixel display area 101, and the first groove 141 is located in the center of the pixel display area 101, as such, the display lights 201 from the flat portion 1501 can be converged at an all-directional angles, to reflect out of the light-emitting device, thereby improving light efficiency.

Specifically, the first organic insulating layer 14 is provided with one first groove 141 in a pixel display area 101, and the first groove 141 is located in the center of the pixel display area 101, that is, the center of the opening 161 is located in the first groove 141.

In some embodiments, in the top view, the shape of the first groove 141 matches the shape of the pixel display area 101.

Specifically, as shown in FIG. 4, in a case that the shape of the pixel display area 101 is a regular shape, the shape of the first groove 141 matches the shape of the pixel display area 101. An outline of the pixel display area 101 has a circular shape, a ring shape, an elliptical shape, a rectangular shape, a square shape, or the like. An outline of the first groove 141 has a circular shape, a ring shape, an elliptical shape, a rectangular shape, a square shape, or the like. For example, in a case that the shape of the pixel display area 101 is a circular shape, and the shape of the first groove 141 is also a circular shape. As such, the display lights 201 from the flat portion 1501 are all reflected by the first groove 141, thereby improving the light efficiency.

Specifically, as shown in FIG. 5, in a case that the shape of the pixel display area 101 is an irregular shape, the shape of the first groove 141 matches the shape of the pixel display area 101, and the display lights 201 of the flat portion 1501 may be uniformly collected in the first groove 1411 and emitted out of the first groove 141, thereby improving the light efficiency. Referring to FIG. 5, a top-section of the first groove 141 has a first arc 1411 and a second arc 1412, and the first arc 1411 is connected with the second arc 1412. Further, the first arc 1411 has a greater curvature radius than the second arc 1412.

In some embodiments, the first organic insulating layer 14 is provided with a plurality of first grooves 141 in a pixel display area 101, the plurality of first grooves 141 are uniformly arranged in the pixel display area.

Specifically, as shown in FIG. 6, in a case that the length or the size of the pixel display area 101 is relatively large, and the length or the size of the first groove 141 is relatively small, the light-emitting device may include a plurality of first grooves 141, and the plurality of first grooves 141 are uniformly arranged in the pixel display area 101. As such, the display lights 201 from the flat portion 1501 can be uniformly reflected out of the plurality of first grooves 141, thereby improving light efficiency.

It should be noted that, as shown in FIGS. 4 to 6, the first electrode 151 of the display panel is connected to the drain or source of the thin film transistor through the first through-hole 104.

The foregoing has described in detail a display panel according to an embodiment of the present application, and examples are used to illustrate the principles and embodiments of the present application. The description of the above embodiments is merely provided to assist in understanding the method of the present application and the core concepts thereof. At the same time, variations will occur to those skilled in the art in both the detailed embodiment and the scope of application in accordance with the teachings of the present application. In view of the foregoing, the present description should not be construed as limiting the application.

1. A display panel, comprising a plurality of pixel display areas, and a non-display area between the pixel display areas;
wherein the display panel further comprises:
a substrate;
an inorganic insulating layer disposed on a side of the substrate;
a first metal layer disposed on a side of the inorganic insulating layer away from the substrate, wherein the first metal layer comprises a plurality of first metal traces, each of the first metal traces comprises a first trace portion overlapped with a corresponding one of the pixel display areas;
a first organic insulating layer disposed on a side of the first metal layer away from the substrate, wherein a first groove is provided on a side of the first organic insulating layer away from the substrate, and the first groove is disposed corresponding to the first trace portion; and
a second metal layer disposed on the side of the first organic insulating layer away from the substrate, wherein the second metal layer comprises a plurality of first electrodes disposed corresponding to the pixel display area; and
wherein each of the first electrodes covers the first groove, and a minimum distance between the first electrode and the first trace portion of the first metal trace corresponding to the first electrode is greater than or equal to 1.2 μm.

2. The display panel of claim 1, wherein the minimum distance between the first electrode and the first trace portion of the first metal trace corresponding to the first electrode is less than or equal to 4 μm.

3. The display panel of claim 1, wherein the first organic insulating layer has a thickness less than or equal to 4 μm.

4. The display panel of claim 1, wherein the first organic insulating layer comprises:
a first organic sub-insulating layer disposed on the side of the first metal layer away from the substrate; wherein a minimum distance between an area of the first organic sub-insulating layer corresponding to the first metal trace and the substrate is greater than a minimum distance between the first metal trace and the substrate; and
a second organic sub-insulating layer disposed on a side of the first organic sub-insulating layer away from the substrate, wherein the first groove is disposed on a side of the second organic sub-insulating layer away from the substrate.

5. The display panel of claim 4, wherein a thickness of the first organic sub-insulating layer on the inorganic insulating layer is greater than a thickness of the first metal layer on the inorganic insulating layer.

6. The display panel of claim 4, wherein a thickness of the first organic sub-insulating layer in an area not corresponding to the first metal trace is less than or equal to 2 μm; and
a thickness of the second organic sub-insulating layer in the area not corresponding to the first metal trace is less than or equal to 2 μm.

7. The display panel of claim 1, further comprising:
a third metal layer disposed between the inorganic insulating layer and the first metal layer, wherein the third metal layer comprises a plurality of second metal traces, each of the second metal traces comprises a second trace portion overlapped with the pixel display area; and
a second organic insulating layer disposed between the third metal layer and the first metal layer;
wherein the second trace portion and the first trace portion are at least partially overlapped in the pixel display area.

8. The display panel of claim 7, wherein a minimum distance between the second trace portion and the first trace portion is greater than or equal to 1.2 μm.

9. The display panel of claim 1, wherein the first electrode comprises a flat portion and a recessed portion, the recessed portion is attached with the first groove, and the flat portion is disposed around the first groove.

10. The display panel of claim 1, further comprises a pixel definition layer and a second electrode, wherein the pixel definition layer is disposed on the second metal layer, and the second electrode is disposed on the pixel definition layer.

11. The display panel of claim 10, wherein the pixel definition layer has an opening, and the opening exposes the first electrode.

12. The display panel of claim 1, wherein a depth of the first groove is greater than 0 and less than or equal to 0.8 μm.

13. The display panel of claim 12, wherein an included angle between a side wall of the first groove and a bottom surface of the first groove ranges from 120° to 160°.

14. The display panel of claim 1, wherein the first organic insulating layer is provided with one first groove in the pixel display area, and the first groove is located at a center of the pixel display area.

15. The display panel of claim 14, wherein a shape of the first groove matches a shape of the pixel display area.

16. The display panel of claim 15, wherein an outline of the first groove has a circular shape, a ring shape, an elliptical shape, a rectangular shape, and a square shape.

17. The display panel of claim 15, wherein an outline of the first groove has a first arc and a second arc, and the first arc is connected with the second arc.

18. The display panel of claim 17, wherein the first arc has a greater curvature radius than the second arc.

19. The display panel of claim 1, wherein the first organic insulating layer is provided with a plurality of first grooves in the pixel display area, the first grooves are uniformly arranged in the pixel display area.

20. The display panel of claim 1, wherein a first through-hole is provided on the first electrode, to connect the first electrode to a thin film transistor.
